(19) United States
(12) Patent Application Publication
(10) Pub. No.: US 2023/0307336 A1
(43) Pub. Date: Sep. 28, 2023

(54) PACKAGE SUBSTRATES EMPLOYING PAD METALLIZATION LAYER FOR INCREASED SIGNAL ROUTING CAPACITY, AND RELATED INTEGRATED CIRCUIT (IC) PACKAGES AND FABRICATION METHODS

(71) Applicant: QUALCOMM Incorporated, San Diego, CA (US)

(72) Inventors: Joan Rey Villarba Buot, Escondido, CA (US); Zhijie Wang, San Diego, CA (US); Aniket Patil, San Diego, CA (US); Hong Bok We, San Diego, CA (US)

(21) Appl. No.: 17/656,477

(22) Filed: Mar. 25, 2022

(51) Int. Cl. H01L 23/498; H01L 21/48

(52) U.S. Cl. CPC H01L 23/49822; H01L 23/49894; H01L 21/4857

(57) ABSTRACT

Package substrates employing a pad metallization layer for increased signal routing capacity, and related integrated circuit (IC) packages and fabrication methods. To support increased signal routing density in an IC package while mitigating an increase in overall IC package thickness, an outer metallization layer of the package substrate is provided as a thinner, pad metallization layer. A metal layer in the pad metallization layer includes metal pads for forming external connections to the package substrate. This allows an area in the adjacent metallization layer that would otherwise have larger width metal pads for forming external interconnects, to be used for other signal routing within the package substrate. This can increase the overall signal routing density of the package substrate while mitigating the increase in overall package substrate thickness if a full-sized additional metallization layer were added to the package substrate.

### BACKGROUND

### I. Field of the Disclosure

The field of the disclosure relates to integrated circuit (IC) packages, and more particularly to design and manufacture of package substrates that support signal routing to a semiconductor die(s) in the IC package.

### II. Background

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a package substrate to provide physical support and an electrical interface to the die(s). The package substrate includes one or more metallization layers that include metal interconnects (e.g., metal traces, metal lines) with vias coupling the metal interconnects together between adjacent metallization layers to provide electrical interfaces between the die(s). The die(s) is electrically interfaced to metal interconnects exposed in a top or outer metallization layer of the package substrate to electrically couple the die(s) to the metal interconnects of the package substrate. For example, the package substrate may include an embedded trace substrate (ETS) layer adjacent to the die to facilitate higher density bump/solder joints for coupling the die(s) to the package substrate. Metal interconnects in the outer metallization layer are coupled to other metal interconnects in other, lower metallization layers in the package substrate to provide signal routing paths to a coupled die. For example, a package substrate may be a three-layer (3L) ETS package substrate with three (3) metallization layers stacked in a vertical direction.

Some IC packages are known as “hybrid” IC packages, which include multiple die packages with respective dies for different purposes or applications. For example, a hybrid IC package may be an application die, such as a communications modem or processor (including a system). The hybrid IC package could also include, for example, one or more memory dies to provide memory to support data storage and access by the application die. Multiple dies could be disposed in a single die layer and disposed adjacent to each other in a horizontal direction on a package substrate in the IC package. The multiple dies could also be provided in their own respective die packages that are stacked on top of each other in a three-dimensional (3D) arrangement as an overall 3DIC package. An interposer can be disposed between the die packages to support providing electrical connections between the stacked dies in the package. 3DIC packages may be desired to reduce the cross-sectional area of the package. In a 3DIC package, a first, bottom die directly supported on a package substrate is electrically coupled through die interconnects to metallization layers of the package substrate to provide signal routing paths for the die in the package substrate. Other stacked dies that are not directly adjacent to the package substrate in the 3DIC package can be electrically coupled to the package substrate by wire bonds and/or intermediate interposers to provide die-to-die (D2D) connections between the multiple stacked dies.

As die size in an IC package increases, the number connections between the die(s) and the package substrate of the IC package also typically increases to provide the necessary signal routing paths between the die(s) and the package substrate. An increase in the number of signal routing paths leads to the need to support a higher density of signal routing space in a package substrate of the IC package. This may require the number of metallization layers in the package substrate to be increased to accommodate a higher density of signal routing paths. However, adding additional metallization layers to the package substrate increases the overall IC package height and thickness, which may cause the IC package to exceed its overall package thickness requirement.

### SUMMARY OF THE DISCLOSURE

Aspects disclosed herein include package substrates employing a pad metallization layer for increased signal routing capacity. The package substrates are configured to be employed in an integrated circuit (IC) package to provide a mounting structure and signal routing for a semiconductor die(s) (“die(s)”). Related fabrication methods are also disclosed. The package substrate includes one or more metallization layers that each include metal interconnects for providing signal routing paths. A die(s) is coupled to metal interconnects in a first outer metallization layer of the package substrate to provide an electrical coupling between the die(s) and the package substrate for signal routing. External interconnects (e.g., ball grid array (BGA) interconnects) are formed in contact with metal pads in a second outer metallization layer to provide external connections to the IC package and the die(s) therein. As the signal routing density requirements for the IC package increase, additional metallization layers may be required in the package substrate. The additional metallization layers contribute to an increase in overall IC package thickness in an undesired manner. In exemplary aspects, to support increased signal routing density in an IC package while mitigating an increase in overall IC package thickness, the second outer metallization layer of the package substrate is provided as an added pad metallization layer to the package substrate. The pad metallization layer includes a metal layer that includes metal pads for forming external connections to the package substrate. The pad metallization layer also includes a pad via layer that includes vias coupled to the metal pads and to metal interconnects in an adjacent, internal metallization layer to provide signal routing paths between external interconnects and the package substrate. In one example, the pad metallization layer is a dedicated pad metallization layer in that its metal layer only includes metal pads for forming external connections and does not include metal interconnects used for internal signal routing in the package substrate. The metal pads for forming external interconnects that would otherwise be in an adjacent, internal metallization layer in the package substrate are in essence, moved down to this added, pad metallization layer. This allows the area in the adjacent metallization layer that would otherwise have larger width metal pads for forming external interconnects, to be used for providing additional, smaller width metal interconnects to provide for other signal routing within the package substrate. Thus, the pad metallization layer allows the adjacent, internal metallization layer in the package substrate to have an increased density of metal interconnects that are used for internal signal routing in the package substrate to increase the overall signal routing density of the package substrate with a reduced increase in overall IC package thickness.

In exemplary aspects, the pad metallization layer can be provided as a thinner metallization layer in the package substrate, because the pad metallization layer is not formed with a glass material or cloth, such as a pre-impregnated glass (PPG) layer. For example, the pad via layer in the pad metallization layer may be formed as a photo-imagable dielectric (PID) layer that does not include a glass cloth material. It may not be necessary to form the pad via layer of the pad metallization layer as a PPG layer to provide added stability in the package substrate, because the other metallization layers in the package substrate may be sufficiently rigid to provide stability to reduce or avoid warpage. Also, by providing the pad via layer in the pad metallization layer as a thinner layer, this reduces the height of the vias that are formed to couple the metal pads in the pad metallization layer to metal interconnects in the adjacent, internal metallization layer. The reduced height vias in the pad metallization layer also allow the coupled metal interconnects in the adjacent, internal metallization layer to be of reduced width, thus providing additional area in the adjacent metallization layer to provided additional metal interconnects used for internal signal routing in the package substrate to support higher density signal routing. A reduced height via in the pad metallization layer also has less risk of dimple formation in fabrication. This may allow these vias in the pad metallization layer to be formed using an exposure and development process, as opposed to, for example, a laser drilling and fill process being necessary.

Also, in other exemplary aspects, because the pad via layer in the pad metallization layer being of a reduced thickness reduces the risk of dimple formation in the vias, this can also allow the metal pads formed in the metal layer of the pad metallization layer to also be of a reduced thickness. This contributes to a reduction in the thickness of the metal layer in the pad metallization layer, thus contributing to a reduction in thickness of the pad metallization layer as compared to other metallization layers in the package substrate. A thinner metal layer with thinner metal pads in the pad metallization layer also reduces the coefficient of thermal expansion (CTE) of the package substrate than would otherwise be present if the metal layer in the pad metallization layer were thicker. This assists in avoiding or reducing warpage in the IC package with the addition of the pad metallization layer in the package substrate. For example, the metal layer in the pad metallization layer may be a 0.5 thickness metallization layer, meaning it is half or approximately half of the thickness of other metal layers in the other metallization layers in the package substrate as 1.0 thickness metallization layers. Thus, in this example, if the package substrate includes three (3) metallization layers each with 1.0 thickness metal layers, adding the pad metallization layer with a 0.5 metal layer to the package substrate provides 3.5 metal layers total in the package substrate that contribute to the overall thickness of the package substrate. This would be opposed to, in this example, adding an additional metallization layer for increased signal routing density that has a full size 1.0 thickness metal layer, which would provide a thicker, 4.0 metal layer package substrate for the IC package.

In this regard, in one exemplary aspect, a package substrate is provided. The package substrate comprises a first metallization layer comprising a first metal layer having a first thickness. The first metal layer comprises one or more first metal interconnects. The package substrate also comprises a pad metallization layer comprising a first surface disposed adjacent to the first metallization layer and a second surface opposite the first surface. The pad metallization layer comprises a pad metal layer having a second thickness less than the first thickness. The pad metal layer comprises one or more metal pads adjacent to the second surface and each coupled to a first metal interconnect of the one or more metal interconnects. The package substrate also comprises one or more external interconnects each coupled to a metal pad of the one or more metal pads.

In another exemplary aspect, a method of fabricating a package substrate for an IC package is provided. The method comprises forming a first metallization layer comprising forming a first metal layer having a first thickness, and forming one or more first metal interconnects in the first metal layer. The method also comprises forming a pad metallization layer comprising a first surface adjacent to the first metallization layer and a second surface opposite the first surface. Forming the pad metallization layer comprises forming a pad metal layer having a second thickness less than the first thickness, forming one or more metal pads in the pad metal layer adjacent to the second surface, and coupling each metal pad of the one or more metal pads to a first metal interconnect of the one or more metal interconnects. The method also comprises forming one or more external interconnects each coupled to a metal pad of the one or more metal pads.

### BRIEF DESCRIPTION OF THE FIGURES

FIG. 1 is a side view of an integrated circuit (IC) package in the form of a three-dimensional IC (3DIC) package that includes stacked semiconductor dies (“dies”) and a package substrate that includes a pad metallization layer that has a metal layer with metal pads for forming external metal interconnects to provide for increased signal routing capacity in an internal adjacent metallization layer in the package substrate;

FIGS. 2A and 2B are side views of the package substrate that includes a pad metallization layer in the IC package in FIG. 1;

FIG. 3A is a side view of the package substrate in FIGS. 2A and 2B;

FIG. 3B is a top view of the metal interconnects in an internal metallization layer adjacent to the dedicated pad metallization layer in the package substrate in FIGS. 2A and 2B, to illustrate the increased density of signal routing paths in the adjacent metallization layer made possible by providing the metal pads for external interconnects in the pad metallization layer;

FIG. 4A is a side view of an alternative package substrate that can be provided in an IC package, wherein the package substrate includes an additional, full size outer metallization layer that is not dedicated to metal pads for external interconnects;

FIG. 4B is a top view of the metal interconnects in the outer metallization layer in the IC package in FIG. 4A to illustrate the increased density of signal routing paths in outer metallization layer;

FIG. 5A is a top view of another signal routing design that can be provided by metal interconnects formed in the internal metallization layer adjacent to the pad metallization layer in the package substrate in FIGS. 2A and 2B;

FIG. 5B is a top view of another signal routing design that can be provided by metal interconnects formed in the internal metallization layer adjacent to the pad metallization layer in the package substrate in FIGS. 2A and 2B;

FIG. 6 is a flowchart illustrating an exemplary fabrication process of fabricating a package substrate that includes a pad metallization layer that has a metal layer with metal pads for forming external metal interconnects to provide for increased signal routing capacity in an internal adjacent metallization layer in the package substrate, including but not limited to the package substrates in FIGS. 1-3A, and with the signal routing paths in FIGS. 3B and 5A-5B;

FIGS. 7A-7C is a flowchart illustrating another exemplary fabrication process of fabricating a package substrate includes a pad metallization layer that has a metal layer with metal pads for forming external metal interconnects to provide for increased signal routing capacity in an internal adjacent metallization layer in the package substrate, including but not limited to the package substrates in FIGS. 1-3A, and with the signal routing paths in FIGS. 3B and 5A and 5B;

FIGS. 8A-8E are exemplary fabrication stages during fabrication of a package substrate includes a pad metallization layer that has a metal layer with metal pads for forming external metal interconnects to provide for increased signal routing capacity in an internal adjacent metallization layer in the package substrate, according to the fabrication process in FIGS. 7A-7C;

FIG. 9 is a block diagram of an exemplary processor-based system that can include components that can include an IC package that includes a package substrate that includes a pad metallization layer that has a metal layer with metal pads for forming external metal interconnects to provide for increased signal routing capacity in an internal adjacent metallization layer in the package substrate, including but not limited to the package substrates in FIGS. 1-3A and 8A-8E, and with the signal routing paths in FIGS. 3B and 5A-5B, and according to the exemplary fabrication processes in FIGS. 6-7C; and

FIG. 10 is a block diagram of an exemplary wireless communications device that includes radio-frequency (RF) components that can include IC package that includes a package substrate that includes a pad metallization layer that has a metal layer with metal pads for forming external metal interconnects to provide for increased signal routing capacity in an internal adjacent metallization layer in the package substrate, including but not limited to the package substrates in FIGS. 1-3A and 8A-8E, and with the signal routing paths in FIGS. 3B and 5A-5B, and according to the exemplary fabrication processes in FIGS. 6-7C.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include package substrates employing a reduced thickness, pad metallization layer for increased signal routing capacity. The package substrates are configured to be employed in an integrated circuit (IC) package to provide a mounting structure and signal routing for a semiconductor die(s) (“die(s)”). Related fabrication methods are also disclosed. The package substrate includes one or more metallization layers that each include metal interconnects for providing signal routing paths. Die interconnects of a die(s) are coupled to metal interconnects in a first outer metallization layer of the package substrate to provide an electrical coupling between the die(s) and the package substrate for signal routing. External interconnects (e.g., ball grid array (BGA) interconnects) are formed in contact with metal pads in a second outer metallization layer to provide external connections to the IC package and the die(s) therein. As the signal routing density requirements for the IC package increase, additional metallization layers may be required in the package substrate. The additional metallization layers contribute to an increase in overall IC package thickness in an undesired manner. In exemplary aspects, to support increased signal routing density in an IC package while mitigating an increase in overall IC package thickness, the second outer metallization layer of the package substrate is provided as an added pad metallization layer to the package substrate. The pad metallization layer includes a metal layer that includes metal pads for forming external connections to the package substrate. The pad metallization layer also includes a pad via layer that includes vias coupled to the metal pads and to metal interconnects in an adjacent, internal metallization layer to provide signal routing paths between external interconnects and the package substrate. In one example, the pad metallization layer is a dedicated pad metallization layer in that its metal layer only includes metal pads for forming external connections and does not include metal interconnects used for internal signal routing in the package substrate. The metal pads for forming external interconnects that would otherwise be in an adjacent, internal metallization layer in the package substrate are in essence, moved down to this added, pad metallization layer. This allows the area in the adjacent metallization layer that would otherwise have larger width metal pads for forming external interconnects, to be used for providing additional, smaller width metal interconnects to provide for other signal routing within the package substrate. Thus, the pad metallization layer allows the adjacent, internal metallization layer in the package substrate to have an increased density of metal interconnects that are used for internal signal routing in the package substrate to increase the overall signal routing density of the package substrate with a reduced increase in overall IC package thickness.

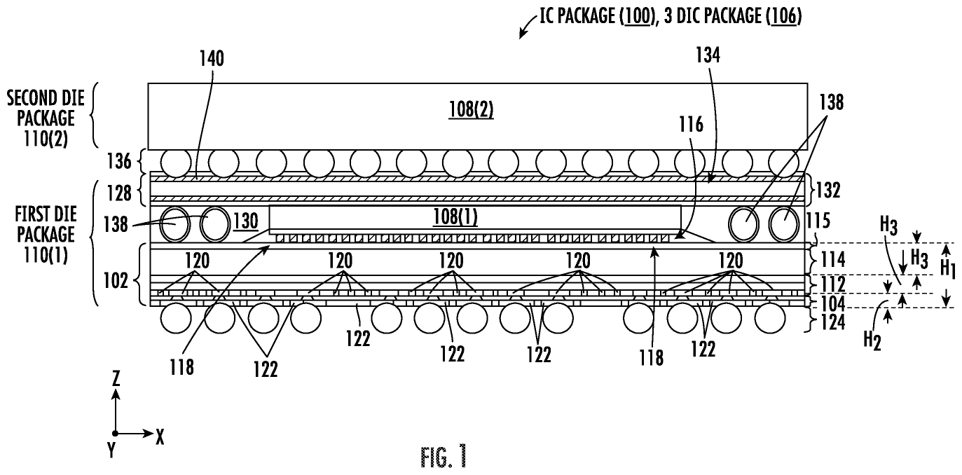

In this regard, FIG. 1 is a side view of an exemplary IC package 100 that includes a package substrate 102 that includes a pad metallization layer 104 that has metal pads for supporting external connections to the package substrate 102. As discussed in more detail below, pad metallization layer 104 allows other metallization layers to have a higher density of metal interconnects to increase the signal routing density of the package substrate 102. Before discussing exemplary details of the pad metallization layer 104, other aspects of the IC package 100 are first described.

In this regard, as shown in FIG. 1, the IC package 100 is a 3D stacked-die IC package 106 that includes multiple dies 108(1), 108(2) that are included in respective die packages 110(1), 110(2) that are stacked on top of each other in the vertical direction (Z-axis direction). The first die package 110(1) of the IC package 100 includes the die 108(1) coupled to the package substrate 102. In this example, the package substrate 102 includes a first outer metallization layer 115 disposed adjacent to a second, internal metallization layer 114, which is adjacent to a third metallization layer 112. The metallization layers 112, 114, 115 provide an electrical interface for signal routing to the die 108(1). The die 108(1) is coupled to die interconnects 116 (e.g., raised metal bumps) that are electrically coupled to metal interconnects 118 in the upper metallization layer 115. The metal interconnects 118 in the upper metallization layer 115 are coupled to metal interconnects 120(1), 120(2) in the metallization layer 114, which are coupled to metal pads 122 in the pad metallization layer 104 discussed in more detail below. In this manner, the package substrate 102 provides interconnections between its metallization layers 112, 114, 115 and the pad metallization layer 104 to provide signal routing to the die 108(1). External interconnects 124 (e.g., ball grid array (BGA) interconnects) are coupled to the metal pads 122 in the pad metallization layer 104 to provide interconnections through the package substrate 102 to the die 108(1) through the die interconnects 116.

As in this example IC package 100 in FIG. 1, to provide a 3D stacking of dies, a second die package 110(2) is provided and coupled to the first die package 110(1) to support multiple dies. For example, the first die 108(1) in the first die package 110(1) may include an application processor, and the second die 108(2) may be a memory die, such as a dynamic random access memory (DRAM) die that provides memory support for the application processor. In this regard, in this example, the first die package 110(1) also includes an interposer substrate 128 that is disposed on a package mold 130 encasing the first die 108(1). The interposer substrate 128 also includes one or more metallization layers 132 that each includes metal interconnects 134 to provide interconnections to the second die 108(2) in the second die package 110(2). The second die package 110(2) is physically and electrically coupled to the first die package 110(1) by being coupled through external interconnects 136 (e.g., solder bumps, BGA interconnects) to the interposer substrate 128. The external interconnects 136 are coupled to the metal interconnects 134 in the interposer substrate 128.

To provide interconnections to route signals from the second die 108(2) through the external interconnects 136 and the interposer substrate 128 to the first die 108(1), vertical interconnects 138 (e.g., metal pillars, metal posts, metal vertical interconnect accesses (vias), such as through-mold vias (TMVs)) are disposed in the package mold 130 of the first die package 106(1). The vertical interconnects 138 extend from the interposer substrate 128 to the package substrate 102 in the vertical direction (Z-axis direction) in this example. The vertical interconnects 138 are coupled to the metal interconnects 134 in the interposer substrate 128. The vertical interconnects 138 are also coupled to the metal interconnects 118 in the upper metallization layer 115 of the package substrate 102. In this manner, the vertical interconnects 138 provide a bridge for interconnections, such as input/output (I/O) connections, between the interposer substrate 128 and the package substrate 102. This provides signal routing paths between the second die 108(2) in the second die package 110(1), and the first die 108(1) and external interconnects 124 through the package substrate 102.

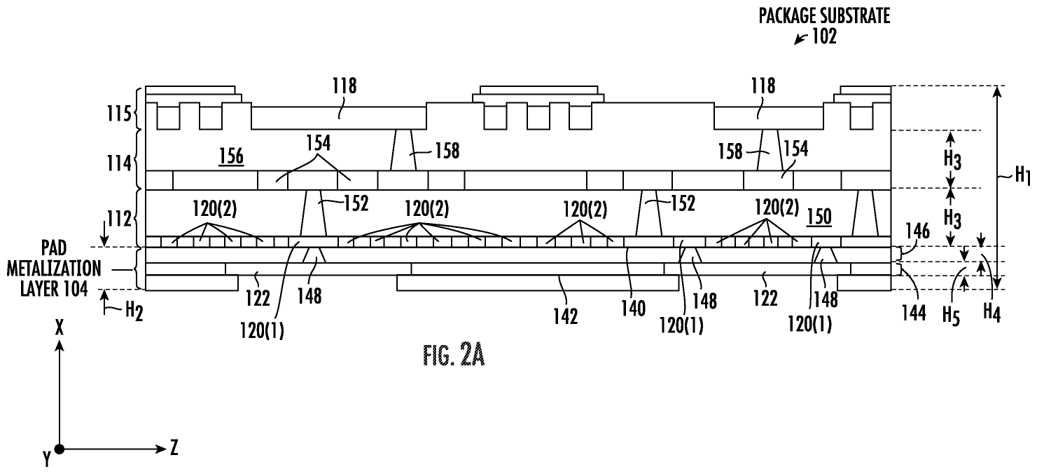

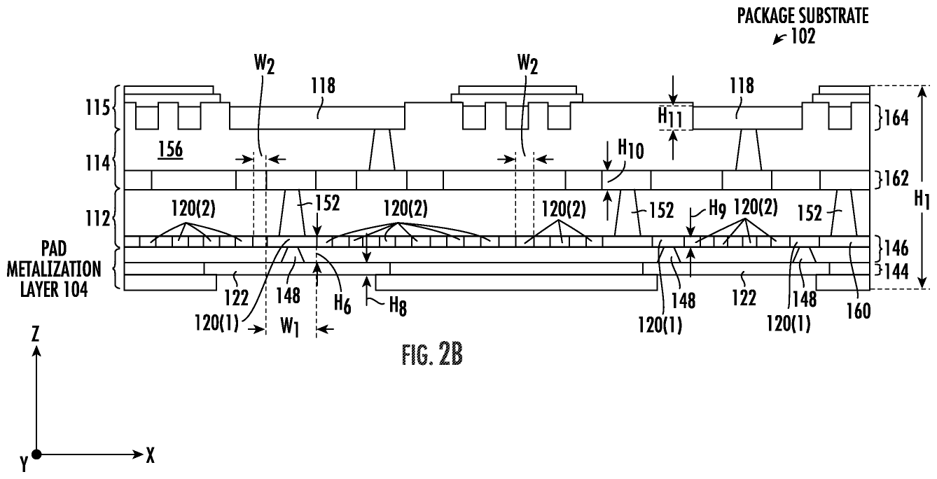

As shown in the more detailed side view of the package substrate 102 in FIG. 2A, the pad metallization layer 104 is an outer metallization layer in the package substrate 102. The pad metallization layer 104 has a first surface 140 disposed adjacent to the metallization layer 112, and a second surface 142 opposite the first surface 140. The pad metallization layer 104 has a pad metal layer 144 that in this example only includes metal interconnects in the form of the metal pads 122 for providing external connect signals paths to the package substrate 102. In this regard, as shown in FIG. 1, the external interconnects 124 are formed in contact with metal pads 122 in the pad metal layer 144 exposed from the pad metallization layer 104, to provide an external interface to the package substrate 102. The metal pads 122 in the pad metal layer 144 are adjacent to the second surface 142 of the pad metallization layer 104. For example, the package substrate 102, and more particularly its external interconnects 124, may be coupled to a circuit board or other substrate to provide a physical and electrical connection to the IC package 100. The pad metallization layer 104 also includes a pad via layer 146 that includes vias 148 coupled to the metal pads 122 and also coupled to metal interconnects 120(1) in the adjacent, internal metallization layer 112 to provide signal routing paths between external interconnects 124 and the package substrate 102. The metallization layer 112 includes a via layer 150 that includes vias 152 coupled to the metal interconnects 120(1) and metal interconnects 154 in the metallization layer 114 to provide a signal routing path between the metallization layers 112, 114. The metallization layer 114 also includes a via layer 156 that includes vias 158 coupled to the metal interconnects 154 and metal interconnects 118 in the metallization layer 115 to provide a signal routing path between the metallization layers 114, 115.

Providing the additional pad metallization layer 104 in the package substrate 102 shown in FIGS. 1-2B can increase the signal routing capacity of the package substrate 102 while minimizing the need to add additional larger sized metallization layers to the package substrate 102. This is because as shown in the package substrate 102 in FIGS. 1-2B, the metal pads 122 for forming external interconnects that would otherwise be in the metallization layer 114 if the pad metallization layer 104 were not present are in essence, moved down to the pad metallization layer 104. In this example, each metal pad 122 in the pad metallization layer 104 is coupled to an external interconnect 124 such that the metal pads 122 in the pad metallization layer 104 are exclusively provided for signal routing to the external interconnects 124 and not internal signal routing in the package substrate 102. Providing the metal pads 122 for forming the external interconnects 124 in the added pad metallization layer 104 provides an additional area in the adjacent metallization layer 112, that would otherwise have the larger width metal pads for forming external interconnects, to be used for providing additional, smaller width metal interconnects 120(2) to provide for other signal routing within the package substrate 102. Thus, the pad metallization layer 104 allows the adjacent, internal metallization layer 114 in the package substrate 102 to have an increased density of metal interconnects 120(2) that are used for internal signal routing in the package substrate 102 to increase the overall signal routing density of the package substrate 102 with a reduced increase in overall IC package thickness H₁ in the Z-axis direction.

In this example, adding the pad metallization layer 104 to the package substrate 102 that includes the metal pads 122 for supporting the external interconnects 124 does increase the thickness of the package substrate 102 and contribute to the height H₁ of the package substrate 102. However, the pad metallization layer 104 in this example has a reduced thickness H₂ in the Z-axis direction over simply providing another metallization layer that is, for example, of the thicknesses H₃ of the other metallization layers 112, 114 in the Z-axis direction in the package substrate 102. Thus, by providing the pad metallization layer 104 in the package substrate 102, the signal routing density is increased in the adjacent metallization layer 112 in the package substrate 102 while only increasing the thickness H₁ of the package substrate by thickness H₂ as opposed to, for example, another metallization layer of thickness H₃.

Also as shown in FIG. 2A, to minimize the thickness H₂ of the pad metallization layer 104 in the package substrate 102, it is desired to reduce the height or thickness H₄ of the pad via layer 146 in the Z-axis direction and the height or thickness H₅ of the pad metal layer 144 in the Z-axis direction, if possible. In this regard, in this example, to reduce the height or thickness H₄ of the pad via layer 146, the pad via layer 146 in the pad metallization layer 104 is not formed with a glass material or cloth, such as a pre-impregnated glass (PPG) layer, in this example. It may not be necessary to form the pad via layer 146 of the pad metallization layer 104 as a PPG layer to provide added stability in the package substrate 102, because the other metallization layers 112, 114, 115 in the package substrate 102 may be sufficiently rigid to provide stability to reduce or avoid warpage. As an example, one, some or all of the metallization layers 112, 114, 115 may be formed from or include a glass material, such as PPG material for example, to increase its rigidity. This allows the pad via layer 146 to be provided of a reduced height or thickness H₄ and/or width in the pad metallization layer 104, and as compared to the height or thickness H₇ and/or width of the via layer 150 in the adjacent metallization layer 112, to reduce the overall height or thickness H₂ of the pad metallization layer 104. This in turn reduces the impact of the pad metallization layer 104 to the overall thickness or height H₁ of the package substrate 102.

For example, the pad via layer 146 and/or its vias 148 may have a height or thickness H₄ between ten (10) micrometers (μm) and fifteen (15) μm, such as ten (10) micrometers (μm). The via layer 150 and/or its vias 152 in the adjacent metallization layer 112 may have a respective height or thickness H₇ between twenty five (25) μm and 45 μm, such as 25 μm. Also, as another example, a ratio of the height or thickness H₇ of the via layer 150 and/or its vias 152 to the height or thickness H₄ of the pad via layer 146 and/or its vias 148 may be at least 1.6.

Also, as shown in another side view of the package substrate 102 in FIG. 2B, by providing the pad via layer 146 as a thinner layer in the pad metallization layer 104, this reduces the height or thickness H₆ of the vias 148 that are formed to couple the metal pads 122 in the pad metallization layer 104 to the metal interconnects 120(1) in the adjacent, internal metallization layer 112. For example, the pad via layer 146 of the pad metallization layer 104 may be formed as a photo-imagable dielectric (PID) layer so that the vias 148 in the pad via layer 146 can be formed from an imaging and development process, as opposed to through laser drilling for example, to reduce the height or thickness H₆ of the vias 148. The vias 148 have a height or thickness H₆ that is less than a height or thickness H₇ of vias 152 in the adjacent metallization layer 112. The reduced height vias 148 in the pad metallization layer 104 also allow the coupled metal interconnects 120(1) in the adjacent, internal metallization layer 112 to be of reduced width W₁, thus providing additional area in the adjacent metallization layer 112 to provided additional metal interconnects 120(2) used for internal signal routing in the package substrate 102 to support higher density signal routing. A reduced height via 148 in the pad metallization layer 104 also has less risk of dimple formation in fabrication. As discussed in more detail below, this may also allow these vias 148 in the pad metallization layer 104 to be formed using an exposure and development process, as opposed to, for example, a laser drilling and fill process being necessary.

Note that as shown in FIG. 2B, the metallization layer 112 adjacent to the pad metallization layer 104 includes metal interconnects 120(1) of width W₁ that are coupled to vias 148 in the via pad layer 146 of the pad metallization layer 104 to provide connectivity between the metallization layer 112 and the external interconnects 124 (FIG. 1). The metallization layer 112 also includes other metal interconnects 120(2) of width W₂ that is less than width W₁ that are not coupled to the vias 148 in the pad metallization layer 104. These other metal interconnects 120(2) are used for internal signal routing in the metallization layer 112 for the package substrate 102. It is by providing the additional pad metallization layer 104 that has the metal pads 122 for providing external connections that additional area is available in metallization layer 112 adjacent to the pad metallization layer 104 for providing additional metal interconnects 120(2) that are not coupled to the metal pads 122 to increase the signal routing density in the metallization layer 112 and thus in the package substrate 102.

Also, in this example, because the pad via layer 146 in the pad metallization layer 104 being of a reduced height or thickness H₄ reduces the risk of dimple formation in the vias 148, this can also allow the metal pads 122 formed in the pad metal layer 144 of the pad metallization layer 104 to also be of a reduced height or thickness H₈. This contributes to a reduction in the height or thickness H₈ of the pad metal layer 144 in the pad metallization layer 104, thus contributing to a reduction in thickness of the pad metallization layer H₂ as compared to other metallization layers 112, 114, for example, in the package substrate 102. A thinner pad metal layer 144 with thinner metal pads 122 in the pad metallization layer 104 can also reduce the coefficient of thermal expansion (CTE) of the package substrate 102 than would otherwise be present if the pad metal layer 144 in the pad metallization layer 104 were thicker. This assists in avoiding or reducing warpage in the IC package 100 with the addition of the pad metallization layer 104 in the package substrate 102.

The height or thickness H₉, H₁₀, H₁₁ of any of the respective metal layers 160, 162, and/or 164 in the metallization layers 112, 114, 115 may be between twelve (12) μm and sixteen (16) μm. For example, the height or thickness H₉, H₁₀, H₁₁ of the respective metal layers 160, 162, 164 may be 12 μm, 12 μm, and 14 μm. The height or thickness of the pad metal layer 144 in the pad metallization layer 104 may be between ten (10) μm and twelve (12) μm. Note that in one example, a ratio of any of the height or thickness H₉, H₁₀, H₁₁ of the respective metal layers 160, 162, and/or 164 in the metallization layers 112, 114, 115, to the height or thickness H₅ of the pad metal layer 144 may be at least 1.2.

As another example, the pad metal layer 144 in the pad metallization layer 104 may be a 0.5 thickness metallization layer, meaning it is half or approximately half of the thickness of other metal layers 160, 162, 164 in the other metallization layers 112, 114, 115 in the package substrate 102 as 1.0 thickness metallization layers. Thus, in this example, with the package substrate 102 including the three (3) metallization layers 112, 114, 115 each with 1.0 thickness metal layers 160, 162, 164, adding the pad metallization layer 104 with a 0.5 pad metal layer 144 to the package substrate 102 provides 3.5 metal layers total in the package substrate 102 that contribute to the overall thickness H₁ of the package substrate 102. This would be opposed to, in this example, adding an additional metallization layer for increased signal routing density that has a full size 1.0 thickness metal layer, like metal layers 160, 162, 164 which would provide a thicker, 4.0 metal layer package substrate for the IC package 100.

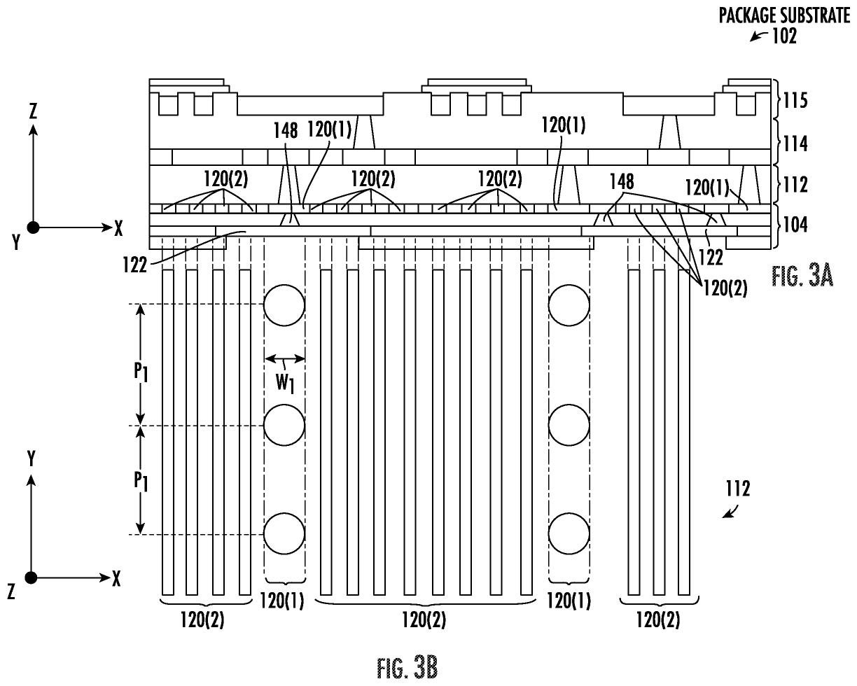

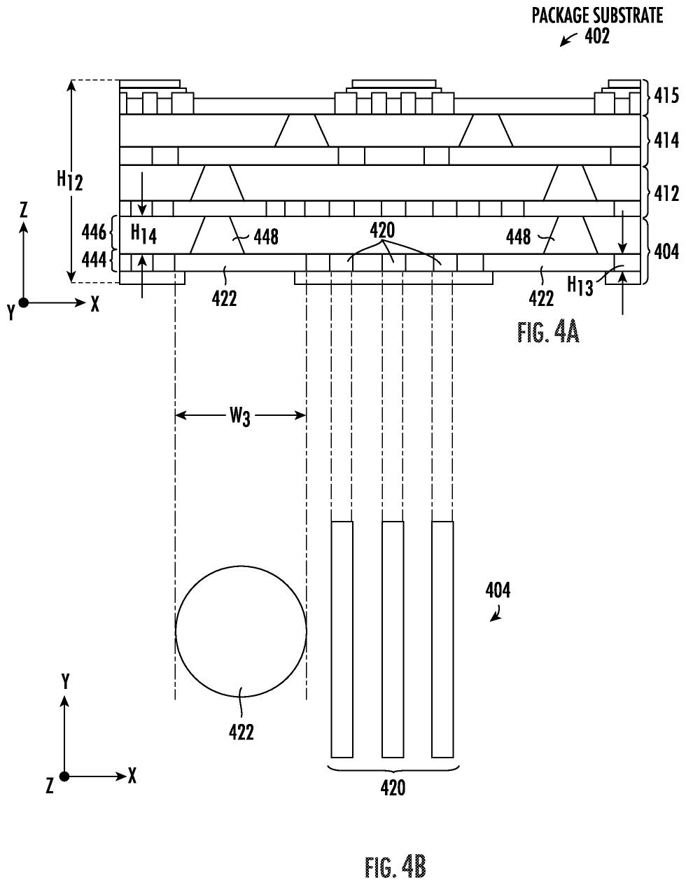

The additional area provided in the metallization layer 112 adjacent to the pad metallization layer 104 in the package substrate 102 for providing additional metal interconnects 120(2) for increased signal routing density is also shown in FIGS. 3A and 3B. FIG. 3A is a side view of the package substrate 102 in FIGS. 2A and 2B. FIG. 3B is a top view of the metal interconnects 120(1), 120(2) routed in the metallization layer 112 that is adjacent to the pad metallization layer 104 in the package substrate 102 shown in FIG. 3A. As shown in FIG. 3B, there are eight metal lines of the metal interconnects 120(2) extending in a horizontal direction in the Y-axis direction between metal interconnects 120(1) that are coupled to the metal pads 122 in the pad metallization layer 104. As discussed above and shown in FIG. 3B, by moving the metal pads 122 in which the external interconnects 124 are formed out of the metallization layer 112 to the additional pad metallization layer 104, the metal interconnects 120(1) can be formed smaller in width W₁. This formation of the smaller sized vias 148 facilitates the smaller sized metal interconnects 120(1) as discussed above. This provides additional space for the formation of other metal interconnects 120(2) for internal signal routing in the metallization layer 112, as opposed to a package substrate 402 like shown in FIG. 4A.

FIG. 4A is a side view of the package substrate 402 that does not include a pad metallization layer, but rather four (4) metallization layers 404, 412, 414, 415. Metallization layers 412, 414, 415 are similar to metallization layers 112, 114, 115 in the package substrate 102 in FIGS. 2A-3B. However, as shown in FIG. 4A and the top view of the metallization layer 404 in FIG. 4B, the package substrate 402 includes a fourth, outer metallization layer 404 in which larger metal interconnects 422 of width W₃ are formed for being coupled to external interconnects. In this example, the outer metallization layer 404 is thicker in height in the Z-axis direction than the pad metallization layer 104 in the package substrate in FIGS. 1-3B. For example, the height or thickness H₁₂ of the outer metallization layer 404 of the package substrate 402 is greater than the height or thickness H₁ of the outer pad metallization layer 104 of the package substrate 102 in FIGS. 1-3A. For example, the height or thickness H₁₂ of the outer metallization layer 404 may be 167 μm as an example, whereas the height or thickness H₁ of the pad metallization layer 104 of the package substrate 102 in FIGS. 1-3A may be 148 μm as an example.

The reduction in height H₁ of the outer pad metallization layer 104 of the package substrate 102 is based on the height or thickness H₅ of the pad metal layer 144 in the pad metallization layer 104 in FIGS. 1-3A being less than the height or thickness H₁₃ of a metal layer 444 in the outer metallization layer 404 in which the metal interconnects 420, 422 are formed. For example, the height or thickness H₅ of the pad metal layer 144 in the pad metallization layer 104 may be eight (8) μm versus twelve (12) μm for the height or thickness H₁₃ of a metal layer 444 in the outer metallization layer 404. Also, the reduction in height H₁ of the outer pad metallization layer 104 of the package substrate 102 is based on the height or thickness H₄ of the pad via layer 146 in the pad metallization layer 104 of the package substrate 102 in FIGS. 1-3A being less than the height or thickness H₁₄ of a via layer 446 in the outer metallization layer 404 in the package substrate 402. For example, the height or thickness H₄ of the pad via layer 146 in the pad metallization layer 104 of the package substrate 102 in FIGS. 1-3A may be ten (10) μm versus twenty-five (25) μm for the height or thickness H₁₄ of a via layer 446 in the outer metallization layer 404 in the package substrate 402.

Also, the metallization layer 404 in the package substrate 402 in FIG. 4A also includes metal interconnects 422 that are of larger width W₃ than the width W₁ of the metal interconnects 120(1) in the pad metallization layer 104 in the package substrate 102 in FIGS. 1A-3 Because of the larger width W₃ of the metal interconnects 422, there is less area available in the outer metallization layer 404 for the formation of metal interconnects 420 for internal signal routing in the metallization layer 404 of the package substrate 402, as compared to the area available for metal interconnects 120(1) in the metallization layer 112 of the package substrate 102 in FIGS. 3A and 3B.

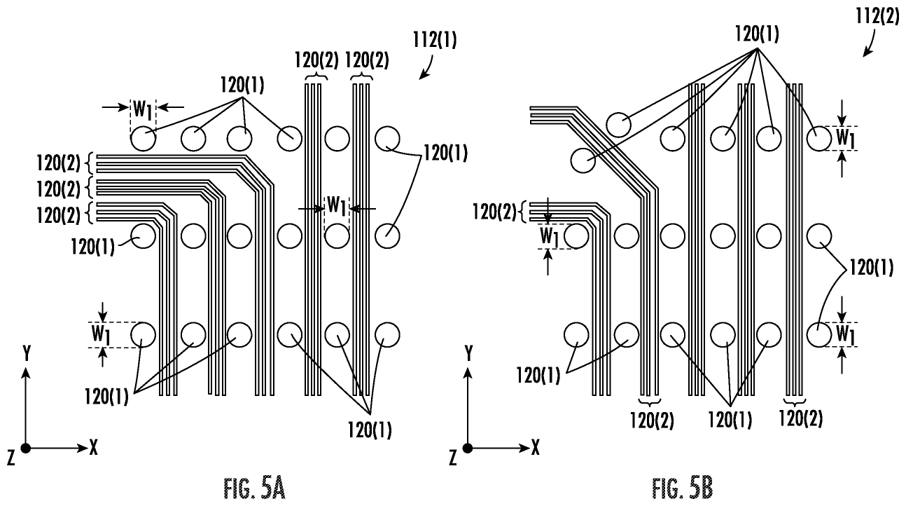

Other routing schemes can be provided in the metallization layer 112 that is adjacent to the pad metallization layer 104 in the package substrate 102 in FIGS. 1-3B other than as shown in FIG. 3B. For example, FIG. 5A is a top view of another signal routing design that can be provided in an alternative metallization layer 112(1) that can be disposed adjacent to the pad metallization layer 104 in the package substrate 102 in FIGS. 1-3B. As shown therein, the metal interconnects 120(1) can be located closer to each other in the X-axis direction, in rows in the Y-axis, than as shown in FIG. 3B. This is possible, because as discussed above, the metal interconnects 120(1) can be of smaller width W₁ due to moving the metal pads 122 into the adjacent pad metallization layer 104. The metal interconnects 120(2) used for internal signal routing are disposed between the adjacent rows of metal interconnects 120(1). The metal interconnects 120(2) can also turn and run in the X-axis direction in addition to the Y-axis direction. FIG. 5B is a top view of yet another signal routing design that can be provided in an alternative metallization layer 112(2) that can be disposed adjacent to the pad metallization layer 104 in the package substrate 102 in FIGS. 1-3B. As shown therein, the metal interconnects 120(1) can be located closer to each other in the X-axis direction, in rows in the Y-axis, than as shown in FIG. 3B. This is possible, because as discussed above, the metal interconnects 120(1) can be of smaller width W₁ due to moving the metal pads 122 into the adjacent pad metallization layer 104. The metal interconnects 120(2) used for internal signal routing are disposed between the adjacent rows of metal interconnects 120(1). The metal interconnects 120(2) can also turn and run in the X-axis direction in addition to the Y-axis direction.

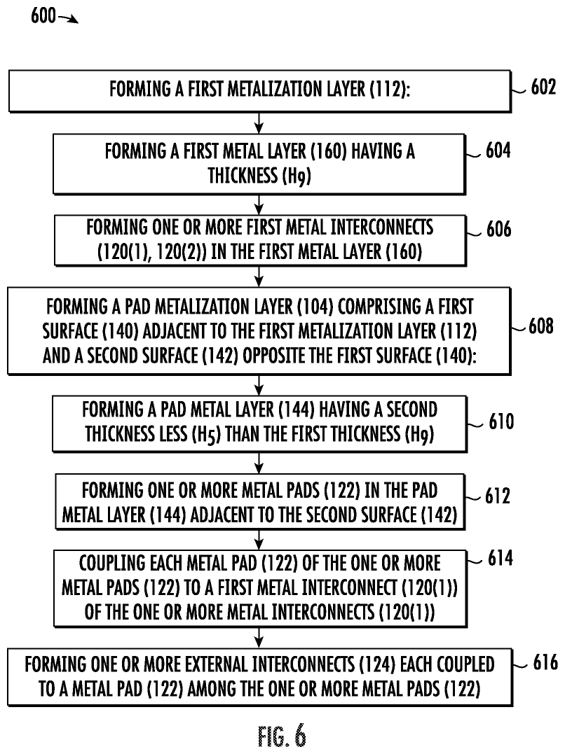

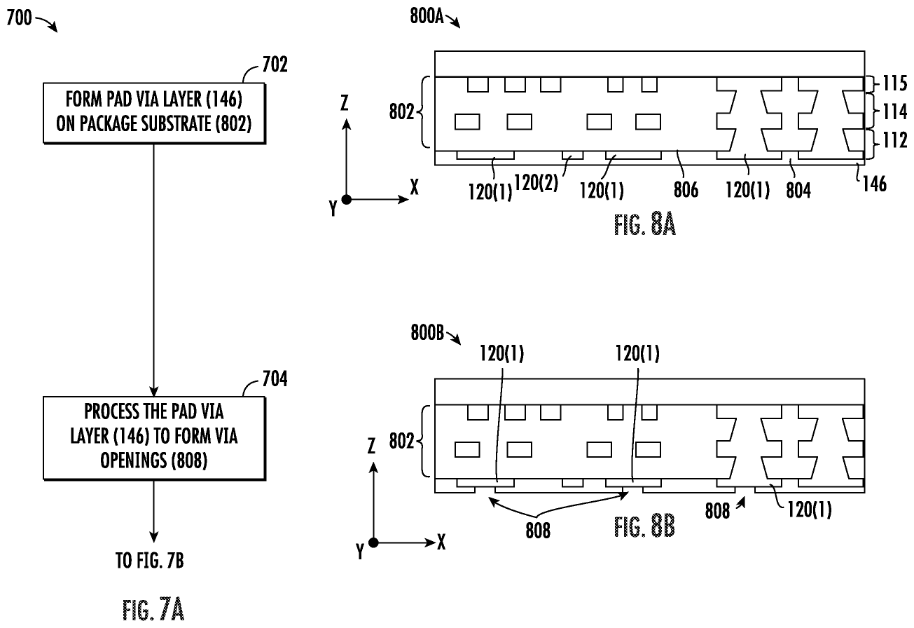

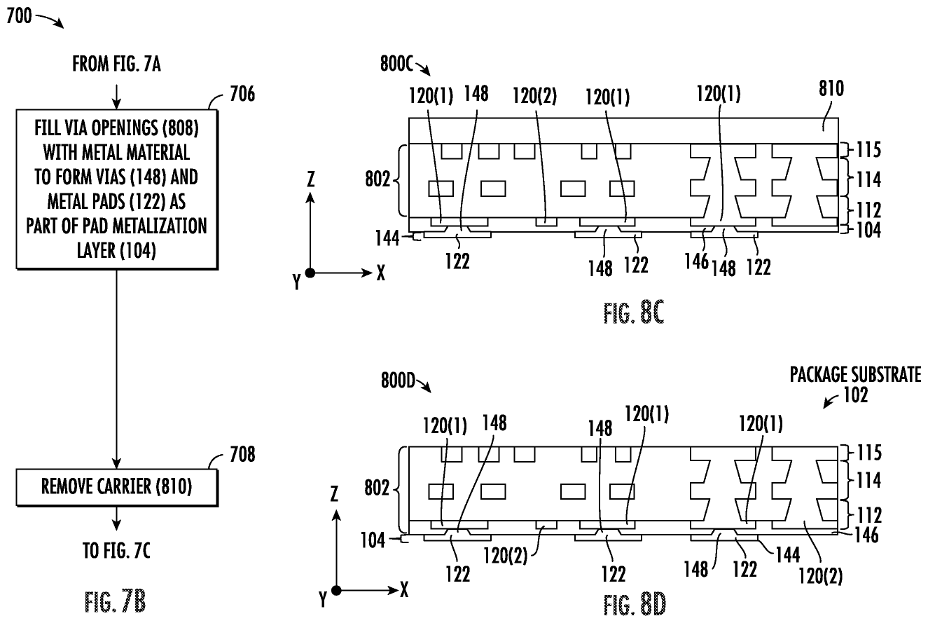

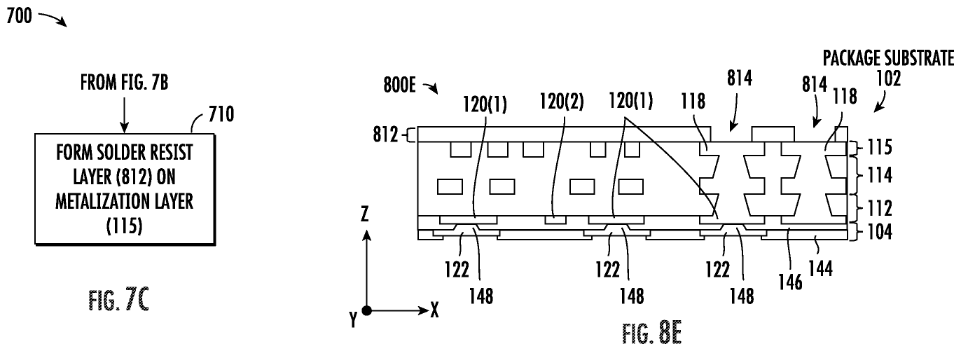

A package substrate for an IC package that includes a pad metallization layer that has a metal layer with metal pads for forming external metal interconnects to provide for increased signal routing capacity in an internal adjacent metallization layer in the package substrate, including but not limited to the package substrates in FIGS. 1-3A and 8A-8E, and with the signal routing paths in FIGS. 3B and 5A-5B, can be fabricated in different fabrication processes. In this regard, FIG. 6 is a flowchart illustrating an exemplary fabrication process 600 of fabricating a package substrate for an IC package, wherein the package substrate includes a pad metallization layer that has a metal layer with metal pads for forming external metal interconnects to provide for increased signal routing capacity in an internal adjacent metallization layer in the package substrate, including but not limited to the package substrates in FIGS. 1-3A and 8A-8E, and with the signal routing paths in FIGS. 3B and 5A-5B, and according to the exemplary fabrication processes in FIGS. 6-7C, and according to any aspects disclosed herein, may be provided in an IC package provided in or integrated into any processor-based device. The fabrication process 600 in FIG. 6 can be used to fabricate the package substrate 102 in FIGS. 1-3B, and with the signal routing paths in FIGS. 3B and 5A-5B, as an example. The fabrication process 800 in FIG. 8 will be discussed in conjunction with the package substrate 102 in FIGS. 1-3B as an example.

In this regard, a first step in the fabrication process 600 in FIG. 6 can include forming a first metallization layer 112 (block 602 in FIG. 6). Forming the first metallization layer 112 can include the steps of forming a first metal layer 160 having a first thickness H₉ (block 604 in FIG. 6), and forming one or more first metal interconnects 120(1), 120(2) in the first metal layer 160 (block 606 in FIG. 6). A next step in fabrication process 600 can be forming a pad metallization layer 104 comprising a first surface 140 adjacent to the first metallization layer 112 and a second surface 142 opposite the first surface 140 (block 608 in FIG. 6). Forming a pad metallization layer 104 can include the steps of forming a pad metal layer 144 having a second thickness less H₅ than the first thickness H₉ (block 610 in FIG. 6), forming one for more metal pads 122 in the pad metal layer 144 adjacent to the second surface 142 (block 612 in FIG. 6), and coupling each metal pad 122 of the one or more metal pads 122 to a first metal interconnect 120(1) of the one or more metal interconnects 120(1) (block 614 in FIG. 6). A next step in the fabrication process 600 can include forming one or more external interconnects 124 each coupled to a metal pad 122 of the one or more metal pads 122 (block 616 in FIG. 6).

Other fabrication processes can also be employed to fabricate a package substrate for an IC package that includes a pad metallization layer that has a metal layer with metal pads for forming external metal interconnects to provide for increased signal routing capacity in an internal adjacent metallization layer in the package substrate, including but not limited to the package substrate 102 in FIGS. 1-3B, and with the signal routing paths in FIGS. 3B and 5A-5B, can be fabricated in different fabrication processes. In this regard, FIGS. 7A-7C is a flowchart illustrating another exemplary fabrication process 700 of fabricating a package substrate that includes a pad metallization layer that has a metal layer with metal pads for forming external metal interconnects to provide for increased signal routing capacity in an internal adjacent metallization layer in the package substrate, including but not limited to the package substrate 102 in FIGS. 1-3B, and with the signal routing paths in FIGS. 3B and 5A-5B. FIGS. 8A-8E are exemplary fabrication stages 800A-800E during fabrication of a package substrate according to the fabrication process 700 in FIGS. 7A-7C. The fabrication process 700 as shown in the fabrication stages 800A-800E in FIGS. 8A-8E are in reference to the package substrate 102 in FIGS. 1-3B, and thus will be discussed with reference to the package substrate 102 in FIGS. 1-3B.

In this regard, as shown the fabrication stage 800A in FIG. 8A, a first exemplary step in the fabrication process 700 is to form the pad via layer 146 on the stack-up of the metallization layers 112, 114, 115 (block 702 in FIG. 7A). The metallization layers 112, 114, 115 have already been fabricated and coupled to each other as part of a three layer (3L) embedded trace substrate (ETS) package substrate 802 at this process step. The pad via layer 416 is formed as a lamination of dielectric material 804 on the bottom surface 806 of the metallization layer 112, which is also disposed on the metal interconnects 120(1), 120(2) of the metallization layer 112. In this example, the dielectric material 804 does not include a glass material, such as a PPG material, as previously discussed to reduce the thickness of the pad via layer 146. Then, as shown the fabrication stage 800B in FIG. 8B, a next exemplary step in the fabrication process 700 is to process the pad via layer 146 to form via openings 808 in which the vias 148 will be formed that are coupled to the metal interconnects 120(1) in the metallization layer (block 704 in FIG. 7A). In this example, the pad via layer 146 is exposed and developed using a lithography process. The pad via layer 146 is not drilled to form the via openings 808 in this example, because the pad via layer 146 is of a sufficient small thickness in the Z-axis direction to be able to form the via openings 808 sufficiently using a lithography process.

Then, as shown the fabrication stage 800C in FIG. 8C, a next exemplary step in the fabrication process 700 is to fill the via openings 808 with a metal material (e.g., copper) to form the vias 148 connected to the metal interconnects 120(1) and to form the metal pads 122 as part of the pad metallization layer 104 (block 706 in FIG. 7B). After the metal material is disposed in the via openings 808 and plated the pad via layer 146, the pad metal layer 144 is exposed and developed to remove metal material in the pad metal layer 144 to leave the metal pads 122 remaining coupled to the vias 148. The pad via layer 146 and pad metal layer 144 form the pad metallization layer 104. Then, as shown the fabrication stage 800D in FIG. 8D, a next exemplary step in the fabrication process 700 is to remove the carrier 810 (shown in FIG. 8C) that was attached to the ETS package substrate 802 to leave the finalized package substrate 102 (block 708 in FIG. 7B). Then, as shown the fabrication stage 800E in FIG. 8E, a next exemplary step in the fabrication process 700 is form a solder resist layer 812 on the metallization layer 115 that will be on a die-side of an IC package (block 710 in FIG. 7C). The solder resist layer 812 is laminated on the metallization layer 115, and then exposed and developed using a lithography process to form openings 814 adjacent to metal interconnects 118 in the metallization layer 115. Die interconnects of a coupled die can be coupled to the metal interconnects 118 in the metallization layer 115 to be electrically coupled to the package substrate 102.

A package substrate that includes a pad metallization layer that has a metal layer with metal pads for forming external metal interconnects to provide for increased signal routing capacity in an internal adjacent metallization layer in the package substrate, including but not limited to the package substrates in FIGS. 1-3A and 8A-8E, and with the signal routing paths in FIGS. 3B and 5A-5B, and according to the exemplary fabrication processes in FIGS. 6-7C, and according to any aspects disclosed herein, may be provided in an IC package provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

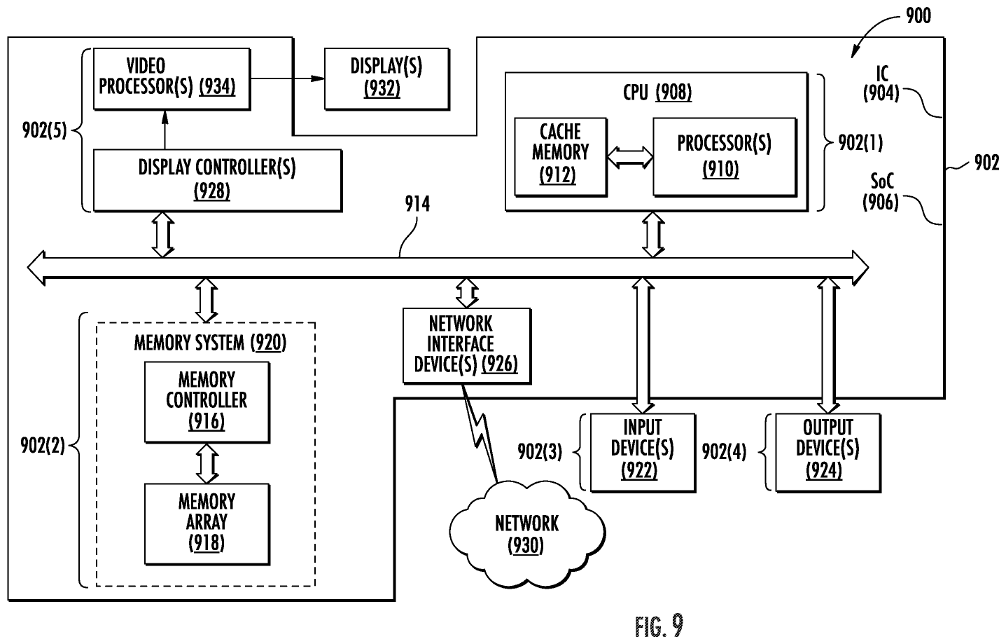

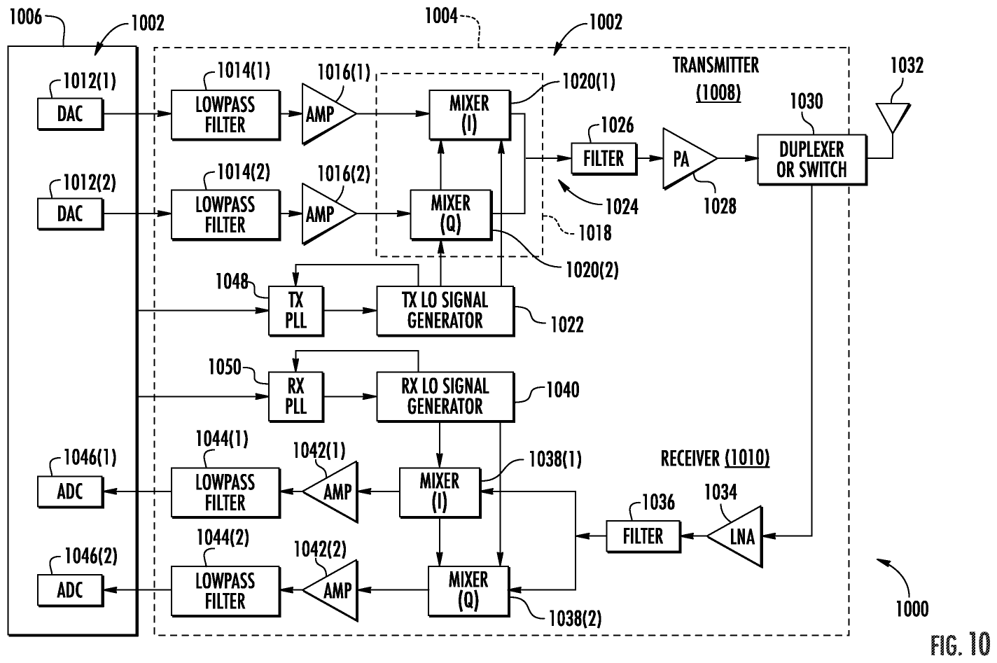

In this regard, FIG. 9 illustrates an example of a processor-based system 900 that includes circuits that can be provided in IC packages 902(1)-902(5). Any of the IC packages 902(1)-902(5) can include a package substrate that includes a pad metallization layer that has a metal layer with metal pads for forming external metal interconnects to provide for increased signal routing capacity in an internal adjacent metallization layer in the package substrate, including but not limited to the package substrates in FIGS. 1-3A and 8A-8E, and with the signal routing paths in FIGS. 3B and 5A-5B, and according to the exemplary fabrication processes in FIGS. 6-7C, and according to any aspects disclosed herein. In this example, the processor-based system 900 may be formed as an IC 904 in an IC package 902 and as a system-on-a-chip (SoC) 906. The processor-based system 900 includes a central processing unit (CPU) 908 that includes one or more processors 910, which may also be referred to as CPU cores or processor cores. The CPU 908 may have cache memory 912 coupled to the CPU 908 for rapid access to temporarily stored data. The CPU 908 is coupled to a system bus 914 and can intercouple master and slave devices included in the processor-based system 900. As is well known, the CPU 908 communicates with these other devices by exchanging address, control, and data information over the system bus 914. For example, the CPU 908 can communicate bus transaction requests to a memory controller 916, as an example of a slave device. Although not illustrated in FIG. 9, multiple system buses 914 could be provided, wherein each system bus 914 constitutes a different fabric.

Other master and slave devices can be connected to the system bus 914. As illustrated in FIG. 9, these devices can include a memory system 920 that includes the memory controller 916 and a memory array(s) 918, one or more input devices 922, one or more output devices 924, one or more network interface devices 926, and one or more display controllers 928, as examples. Each of the memory system 920, the one or more input devices 922, the one or more output devices 924, the one or more network interface devices 926, and the one or more display controllers 928 can be provided in the same or different IC packages 902(5). The input device(s) 922 can include any type of input device, including, but not limited to, input keys, switches, voice processors, etc. The output device(s) 924 can include any type of output device, including, but not limited to, audio, video, other visual indicators, etc. The network interface device(s) 926 can be any device configured to allow exchange of data to and from a network 930. The network 930 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 926 can be configured to support any type of communications protocol desired.

The CPU 908 may also be configured to access the display controller(s) 928 over the system bus 914 to control information sent to one or more displays 932. The display controller(s) 928 sends information to the display(s) 932 to be displayed via one or more video processors 934, which process the information to be displayed into a format suitable for the display(s) 932. The display controller(s) 928 and video processor(s) 934 can be included as ICs in the same or different IC packages 902(5), and in the same or different IC package 902(1) containing the CPU 908, as an example. The display(s) 932 can include any type of display, including, but not limited to, a cathode ray tube (CRT), a liquid crystal display (LCD), a plasma display, a light emitting diode (LED) display, etc.

FIG. 10 illustrates an exemplary wireless communications device 1000 that includes radio frequency (RF) components formed from one or more IC packages 1002, wherein any of the IC packages 1002 can include a package substrate that includes a pad metallization layer that has a metal layer with metal pads for forming external metal interconnects to provide for increased signal routing capacity in an internal adjacent metallization layer in the package substrate, including but not limited to the package substrates in FIGS. 1-3A and 8A-8E, and with the signal routing paths in FIGS. 3B and 5A-5B, and according to the exemplary fabrication processes in FIGS. 6-7C, and according to any aspects disclosed herein. The wireless communications device 1000 may include or be provided in any of the above-referenced devices, as examples. As shown in FIG. 10, the wireless communications device 1000 includes a transceiver 1004 and a data processor 1006. The data processor 1006 may include a memory to store data and program codes. The transceiver 1004 includes a transmitter 1008 and a receiver 1010 that support bi-directional communications. In general, the wireless communications device 1000 may include any number of transmitters 1008 and/or receivers 1010 for any number of communication systems and frequency bands. All or a portion of the transceiver 1004 may be implemented on one or more analog ICs, RF ICs (RFICs), mixed-signal ICs, etc.

The transmitter 1008 or the receiver 1010 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 1010. In the direct-conversion architecture, a signal is frequency-converted between RF and baseband in one stage. The super-heterodyne and direct-conversion architectures may use different circuit blocks and/or have different requirements. In the wireless communications device 1000 in FIG. 10, the transmitter 1008 and the receiver 1010 are implemented with the direct-conversion architecture.

In the transmit path, the data processor 1006 processes data to be transmitted and provides I and Q analog output signals to the transmitter 1008. In the exemplary wireless communications device 1000, the data processor 1006 includes digital-to-analog converters (DACs) 1012(1), 1012(2) for converting digital signals generated by the data processor 1006 into the I and Q analog output signals, e.g., I and Q output currents, for further processing.

Within the transmitter 1008, lowpass filters 1014(1), 1014(2) filter the I and Q analog output signals, respectively, to remove undesired signals caused by the prior digital-to-analog conversion. Amplifiers (AMPs) 1016(1), 1016(2) amplify the signals from the lowpass filters 1014(1), 1014(2), respectively, and provide I and Q baseband signals. An upconverter 1018 upconverts the I and Q baseband signals with I and Q transmit (TX) local oscillator (LO) signals through mixers 1020(1), 1020(2) from a TX LO signal generator 1022 to provide an upconverted signal 1024. A filter 1026 filters the upconverted signal 1024 to remove undesired signals caused by the frequency up-conversion as well as noise in a receive frequency band. A power amplifier (PA) 1028 amplifies the upconverted signal 1024 from the filter 1026 to obtain the desired output power level and provides a transmit RF signal. The transmit RF signal is routed through a duplexer or switch 1030 and transmitted via an antenna 1032.

In the receive path, the antenna 1032 receives signals transmitted by base stations and provides a received RF signal, which is routed through the duplexer or switch 1030 and provided to a low noise amplifier (LNA) 1034. The duplexer or switch 1030 is designed to operate with a specific receive (RX)-to-TX duplexer frequency separation, such that RX signals are isolated from TX signals. The received RF signal is amplified by the LNA 1034 and filtered by a filter 1036 to obtain a desired RF input signal. Down-conversion mixers 1038(1), 1038(2) mix the output of the filter 1036 with I and Q RX LO signals (i.e., LO_I and LO_Q) from an RX LO signal generator 1040 to generate I and Q baseband signals. The I and Q baseband signals are amplified by AMPs 1042(1), 1042(2) and further filtered by lowpass filters 1044(1), 1044(2) to obtain I and Q analog input signals, which are provided to the data processor 1006. In this example, the data processor 1006 includes analog-to-digital converters (ADCs) 1046(1), 1046(2) for converting the analog input signals into digital signals to be further processed by the data processor 1006.

In the wireless communications device 1000 of FIG. 10, the TX LO signal generator 1022 generates the I and Q TX LO signals used for frequency up-conversion, while the RX LO signal generator 1040 generates the I and Q RX LO signals used for frequency down-conversion. Each LO signal is a periodic signal with a particular fundamental frequency. A TX phase-locked loop (PLL) circuit 1048 receives timing information from the data processor 1006 and generates a control signal used to adjust the frequency and/or phase of the TX LO signals from the TX LO signal generator 1022. Similarly, an RX PLL circuit 1050 receives timing information from the data processor 1006 and generates a control signal used to adjust the frequency and/or phase of the RX LO signals from the RX LO signal generator 1040.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. A package substrate, comprising:
a first metallization layer, comprising:
   a first metal layer having a first thickness,
   the first metal layer comprising one or more first metal interconnects;
a pad metallization layer comprising a first surface disposed adjacent to the first metallization layer and a second surface opposite the first surface, the pad metallization layer comprising:
   a pad metal layer having a second thickness less than the first thickness,
   the pad metal layer comprising one or more metal pads adjacent to the second surface and each coupled to a first metal interconnect of the one or more first metal interconnects; and
one or more external interconnects each coupled to a metal pad of the one or more metal pads.

2. The package substrate of clause 1, wherein each metal pad of the one or more metal pads is coupled to an external interconnect of the one or more external interconnects.

3. The package substrate of clause 1 or 2, wherein:
the first metallization layer further comprises one or more second metal interconnects; and
each of the one or more second metal interconnects are not coupled to a metal pad of the one or more metal pads.

4. The package substrate of clause 3, wherein:
the one or more first metal interconnects each have a first width; and
the one or more second metal interconnects each have a second width less than the first width.

5. The package substrate of any of clauses 1 to 4, wherein a ratio of the first thickness of the first metal layer to the second thickness of the pad metal layer is at least 1.2.

6. The package substrate of any of clauses 1 to 4, wherein:
the first thickness of the first metal layer is between twelve (12) micrometers (μm) sixteen (16) μm; and
the second thickness of the pad metal layer is between ten (10) μm and twelve (12) μm.

7. The package substrate of any of clauses 1 to 6, wherein the pad metallization layer further comprises a pad via layer disposed adjacent to the pad metal layer,
the pad via layer comprising one or more pad vias each coupled to a first metal interconnect of the one or more first metal interconnects and to a metal pad of the one or more metal pads.

8. The package substrate of clause 7, wherein the first metallization layer further comprises a first via layer disposed adjacent to the first metal layer,
the first via layer comprising one or more first vias each coupled to a first metal interconnect of the one or more first metal interconnects.

9. The package substrate of clause 8, further comprising:
a second metallization layer adjacent to the first metallization layer such that the first metallization layer is disposed between the second metallization layer and the pad metallization layer,
the second metallization layer comprising a second metal layer comprising one or more second metal interconnects.

10. The package substrate of clause 8 or 9, wherein:
the one or more pad vias have a first height; and
the one or more first vias have a second height greater than the first height.

11. The package substrate of any of clauses 7 to 10, wherein the pad via layer does not contain glass material.

12. The package substrate of any of clauses 8 to 10, wherein:
the pad via layer does not contain glass material; and
the first via layer comprises a glass material.

13. The package substrate of any of clauses 8 to 10 and 12, wherein:
the pad via layer comprises a photo-imagable dielectric (PID) layer; and
the first via layer comprises a pre-impregnated glass (PPG) layer.

14. The package substrate of any of clauses 7 to 13, wherein:
the first via layer has a third thickness; and
the pad via layer has a fourth thickness less than the third thickness.

15. The package substrate of clause 14, wherein a ratio of the third thickness of the first via layer to the fourth thickness of the pad via layer is at least 1.6.

16. The package substrate of clause 14, wherein:
the third thickness of the first via layer is between twenty five (25) μm and forty-five (45) μm; and
the fourth thickness of the pad via layer is between ten (10) μm and fifteen (15) μm.

17. The package substrate of any of clauses 1 to 16 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server, a computer, a portable computer; a mobile computing device; a wearable computing device; a desktop computer; a personal digital assistant (PDA); a monitor; a computer monitor, a television; a tuner, a radio; a satellite radio; a music player, a digital music player; a portable music player; a digital video player; a video player; a digital video disc (DVD) player; a portable digital video player, an automobile; a vehicle component; avionics systems; a drone; and a multicopter.

18. A method of fabricating a package substrate for an integrated circuit (IC) package, comprising:
forming a first metallization layer, comprising:
   forming a first metal layer having a first thickness; and
   forming one or more first metal interconnects in the first metal layer,
forming a pad metallization layer comprising a first surface adjacent to the first metallization layer and a second surface opposite the first surface, wherein forming the pad metallization layer comprises:
   forming a pad metal layer having a second thickness less than the first thickness;
   forming one or more metal pads in the pad metal layer adjacent to the second surface; and
   coupling each metal pad of the one or more metal pads to a first metal interconnect of the one or more first metal interconnects; and
forming one or more external interconnects each coupled to a metal pad of the one or more metal pads.

19. The method of clause 18, wherein forming the one or more external interconnects comprises coupling an external interconnect of the one or more external interconnects to each metal pad of the one or more metal pads.

20. The method of clause 18 or 19, further comprising:
forming one or more second metal interconnects in the first metallization layer; and
not coupling each of the one or more second metal interconnects to a metal pad of the one or more metal pads.

21. The method of clause 20, wherein:
forming the one or more first metal interconnects comprises forming the one or more first metal interconnects each of a first width in the first metal layer; and
forming the one or more second metal interconnects comprises forming the one or more second metal interconnects each of a second width less than the first width in the first metal layer.

22. The method of any of clauses 18 to 21, wherein forming the pad metallization layer further comprises:
forming a pad via layer adjacent to the pad metal layer, and
forming one or more pad vias in the pad via layer each coupled to a first metal interconnect of the one or more first metal interconnects and to a metal pad of the one or more metal pads.

23. The method of clause 22, wherein forming the first metallization layer further comprises:
forming a first via layer adjacent to the first metal layer; and
forming one or more first vias each coupled to a first metal interconnect of the one or more first metal interconnects.

24. The method of clause 23, further comprising forming a second metallization layer adjacent to the first metallization layer such that the first metallization layer is disposed between the second metallization layer and the pad metallization layer,
wherein forming the second metallization layer comprises forming a second metal layer comprising one or more second metal interconnects.

25. The method of any of clauses 22 to 24, wherein:
forming the first via layer in the first metallization layer comprises forming the first via layer having a third thickness; and
forming the pad via layer in the pad metallization layer comprises forming the pad via layer having a fourth thickness less than the third thickness.

What is claimed is:

1. A package substrate, comprising:
a first metallization layer, comprising:
a first metal layer having a first thickness,
the first metal layer comprising one or more first metal interconnects;
a pad metallization layer comprising a first surface disposed adjacent to the first metallization layer and a second surface opposite the first surface, the pad metallization layer comprising:
a pad metal layer having a second thickness less than the first thickness,
the pad metal layer comprising one or more metal pads adjacent to the second surface and each coupled to a first metal interconnect of the one or more first metal interconnects; and
one or more external interconnects each coupled to a metal pad of the one or more metal pads.

2. The package substrate of claim 1, wherein each metal pad of the one or more metal pads is coupled to an external interconnect of the one or more external interconnects.

3. The package substrate of claim 1, wherein:
the first metallization layer further comprises one or more second metal interconnects; and
each of the one or more second metal interconnects are not coupled to a metal pad of the one or more metal pads.

4. The package substrate of claim 3, wherein:
the one or more first metal interconnects each have a first width; and
the one or more second metal interconnects each have a second width less than the first width.

5. The package substrate of claim 1, wherein a ratio of the first thickness of the first metal layer to the second thickness of the pad metal layer is at least 1.2.

6. The package substrate of claim 1, wherein:
the first thickness of the first metal layer is between twelve (12) micrometers (μm) sixteen (16) μm; and
the second thickness of the pad metal layer is between ten (10) μm and twelve (12) μm.

7. The package substrate of claim 1, wherein the pad metallization layer further comprises a pad via layer disposed adjacent to the pad metal layer;
the pad via layer comprising one or more pad vias each coupled to a first metal interconnect of the one or more first metal interconnects and to a metal pad of the one or more metal pads.

8. The package substrate of claim 7, wherein the first metallization layer further comprises a first via layer disposed adjacent to the first metal layer,
the first via layer comprising one or more first vias each coupled to a first metal interconnect of the one or more first metal interconnects.

9. The package substrate of claim 8, further comprising:
a second metallization layer adjacent to the first metallization layer such that the first metallization layer is disposed between the second metallization layer and the pad metallization layer,
the second metallization layer comprising a second metal layer comprising one or more second metal interconnects.

10. The package substrate of claim 8, wherein:
the one or more pad vias have a first height; and
the one or more first vias have a second height greater than the first height.

11. The package substrate of claim 7, wherein the pad via layer does not contain glass material.

12. The package substrate of claim 8, wherein:
the pad via layer does not contain glass material; and
the first via layer comprises a glass material.

13. The package substrate of claim 8, wherein:
the pad via layer comprises a photo-imagable dielectric (PID) layer; and
the first via layer comprises a pre-impregnated glass (PPG) layer.

14. The package substrate of claim 7, wherein:
the first via layer has a third thickness; and
the pad via layer has a fourth thickness less than the third thickness.

15. The package substrate of claim 14, wherein a ratio of the third thickness of the first via layer to the fourth thickness of the pad via layer is at least 1.6.

16. The package substrate of claim 14, wherein:
the third thickness of the first via layer is between twenty five (25) μm and forty-five (45) μm; and
the fourth thickness of the pad via layer is between ten (10) μm and fifteen (15) μm.

17. The package substrate of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer, a mobile computing device; a wearable computing device; a desktop computer, a personal digital assistant (PDA); a monitor, a computer monitor, a television; a tuner; a radio; a satellite radio; a music player, a digital music player, a portable music player, a digital video player; a video player, a digital video disc (DVD) player; a portable digital video player, an automobile; a vehicle component; avionics systems; a drone; and a multicopter.

18. A method of fabricating a package substrate for an integrated circuit (IC) package, comprising:
forming a first metallization layer, comprising:
forming a first metal layer having a first thickness; and
forming one or more first metal interconnects in the first metal layer,
forming a pad metallization layer comprising a first surface adjacent to the first metallization layer and a second surface opposite the first surface, wherein forming the pad metallization layer comprises:
forming a pad metal layer having a second thickness less than the first thickness;
forming one or more metal pads in the pad metal layer adjacent to the second surface; and
coupling each metal pad of the one or more metal pads to a first metal interconnect of the one or more first metal interconnects; and
forming one or more external interconnects each coupled to a metal pad of the one or more metal pads.

19. The method of claim 18, wherein forming the one or more external interconnects comprises coupling an external interconnect of the one or more external interconnects to each metal pad of the one or more metal pads.

20. The method of claim 18, further comprising:
forming one or more second metal interconnects in the first metallization layer, and
not coupling each of the one or more second metal interconnects to a metal pad of the one or more metal pads.

21. The method of claim 20, wherein:
forming the one or more first metal interconnects comprises forming the one or more first metal interconnects each of a first width in the first metal layer; and
forming the one or more second metal interconnects comprises forming the one or more second metal interconnects each of a second width less than the first width in the first metal layer.

22. The method of claim 18, wherein forming the pad metallization layer further comprises:
forming a pad via layer adjacent to the pad metal layer, and
forming one or more pad vias in the pad via layer each coupled to a first metal interconnect of the one or more first metal interconnects and to a metal pad of the one or more metal pads.

23. The method of claim 22, wherein forming the first metallization layer further comprises:
forming a first via layer adjacent to the first metal layer; and
forming one or more first vias each coupled to a first metal interconnect of the one or more first metal interconnects.

24. The method of claim 23, further comprising forming a second metallization layer adjacent to the first metallization layer such that the first metallization layer is disposed between the second metallization layer and the pad metallization layer,
wherein forming the second metallization layer comprises forming a second metal layer comprising one or more second metal interconnects.

25. The method of claim 22, wherein:
forming the first via layer in the first metallization layer comprises forming the first via layer having a third thickness; and
forming the pad via layer in the pad metallization layer comprises forming the pad via layer having a fourth thickness less than the third thickness.
